(19) United States
(12) Patent Application Publication
(10) Pub. No.: US 2022/0301837 A1
(43) Pub. Date: Sep. 22, 2022

(54) FILM DEPOSITION APPARATUS, SPUTTERING TARGET, AND MANUFACTURING METHOD FOR SEMICONDUCTOR DEVICE

(71) Applicant: Kioxia Corporation, Tokyo (JP)

(72) Inventor: Akitsugu HATAZAKI, Yokkaichi (JP)

(73) Assignee: Kioxia Corporation, Tokyo (JP)

(21) Appl. No.: 17/466,399

(22) Filed: Sep. 3, 2021

(30) Foreign Application Priority Data
Mar. 17, 2021 (JP) 2021-043804

(51) Int. Cl. H01J 37/34; C23C 14/35; C23C 14/34

(52) U.S. Cl. CPC H01J 37/3435; H01J 37/3455; C23C 14/35; C23C 14/3407

(57) ABSTRACT

A film deposition apparatus according to an embodiment includes a target including a film deposition material, a backing plate to which the target is to be joined, and a magnet disposed above the backing plate. The backing plate includes a first portion facing the magnet and a second portion in which the intensity of a magnetic field generated by the magnet is lower than in the first portion, the thermal conductivity of a first material included in the first portion is higher than that of a second material included in the second portion, and the Young's modulus of the second material is higher than that of the first material.

### CROSS-REFERENCE TO RELATED APPLICATIONS

This application is based upon and claims the benefit of priority from Japanese Patent Application No. 2021-043804, filed on Mar. 17, 2021; the entire contents of which are incorporated herein by reference.

### FIELD

Embodiments of the present invention relate to a film deposition apparatus, a sputtering target, and a manufacturing method for a semiconductor device.

### BACKGROUND

As a film deposition apparatus, a plasma sputtering apparatus is known. In the plasma sputtering apparatus, plasma is generated between a semiconductor substrate and a target. The plasma ionizes a rare gas, and the resulting rare gas ions collide with the target. Consequently, atoms are sputtered from the surface of the target and thus deposit on the semiconductor substrate. Accordingly, a film is formed on the semiconductor substrate.

### BRIEF DESCRIPTION OF THE DRAWINGS

FIG. 1 is a schematic diagram schematically illustrating the configuration of a film deposition apparatus according to an embodiment;

FIG. 2A is a plan view of a backing plate according to an embodiment;

FIG. 2B is a cross-section along the line X1-X1 illustrated in FIG. 2A;

FIG. 3 is a table illustrating the material characteristics of a target and a backing plate;

FIG. 4A is a plan view of illustrating an exemplary step of producing a backing plate 33;

FIG. 4B is a plan view of illustrating the production step continued from FIG. 4A;

FIG. 5A is a plan view of a backing plate according to Comparative Example;

FIG. 5B is a cross-section along the line X2-X2 illustrated in FIG. 5A;

FIG. 6A is a cross-sectional view of the backing plate according to Comparative Example to which direct-current power is not applied;

FIG. 6B is a cross-sectional view of the backing plate according to Comparative Example to which direct-current power is applied; and

FIG. 7 is a graph illustrating the relationship between direct-current power and the amount of warp of a backing plate.

### DETAILED DESCRIPTION

Embodiments will now be explained with reference to the accompanying drawings. The present invention is not limited to the embodiments.

A film deposition apparatus according to an embodiment includes a target including a film deposition material, a backing plate to which the target is to be joined, and a magnet disposed above the backing plate. The backing plate includes a first portion facing the magnet and a second portion in which the intensity of a magnetic field generated by the magnet is lower than in the first portion, the thermal conductivity of a first material included in the first portion is higher than that of a second material included in the second portion, and the Young's modulus of the second material is higher than that of the first material.

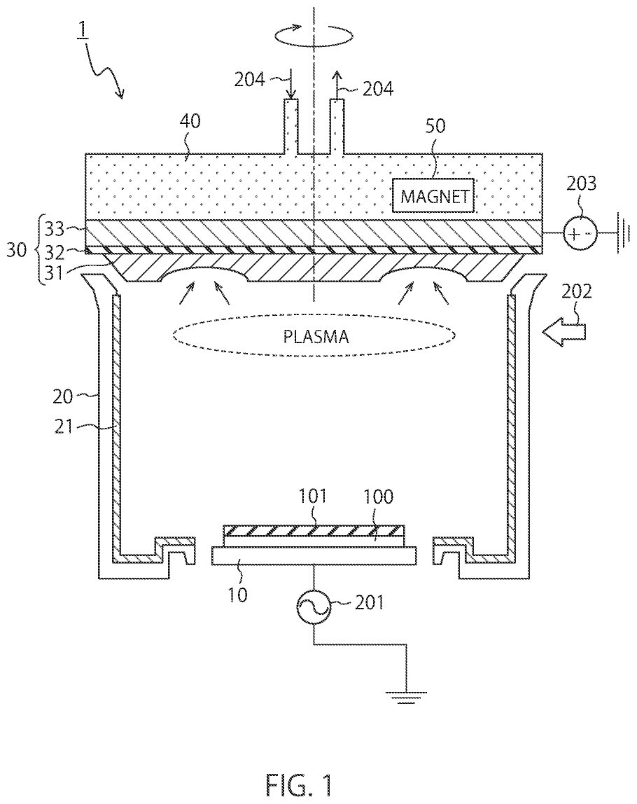

FIG. 1 is a schematic diagram schematically illustrating the configuration of a film deposition apparatus according to an embodiment. A film deposition apparatus 1 illustrated in FIG. 1 is a plasma sputtering apparatus, and includes a stage 10, a chamber 20, a sputtering target 30, a cooling bath 40, and a magnet 50.

A semiconductor substrate 100, which is a deposition target, is placed on the stage 10. The stage 10 is connected to an AC power supply 201. The semiconductor substrate 100 is a silicon substrate, for example. The semiconductor substrate 100 has a film 101 formed thereon by sputtering. The film 101 is a conductive film or an insulating film. In the present embodiment, the film 101 is a silicon nitride (SiN) film.

The chamber 20 houses the semiconductor substrate 100 placed on the stage 10. The stage 10 is disposed at the bottom of the chamber 20. In addition, the sputtering target 30 is disposed above the chamber 20. Further, the chamber 20 has an air hole (not illustrated) through which a rare gas 202 is introduced. For the rare gas 202, an argon (Ar) gas or a nitrogen (N₂) gas can be used, for example.

In the present embodiment, the chamber 20 is made of stainless steel. In addition, the inner face of the chamber 20 has an aluminum layer 21 formed thereon by spraying. The aluminum layer 21 can suppress generation of dust in the chamber 20.

The sputtering target 30 includes a target 31, a bonding material 32, and a backing plate 33.

The target 31 faces the stage 10. The target 31 includes a film deposition material to be deposited as the film 101 on the semiconductor substrate 100. The film deposition material is a silicon single crystal doped with boron (B), for example.

The bonding material 32 joins the target 31 to the backing plate 33. The bonding material 32 contains indium (In), for example.

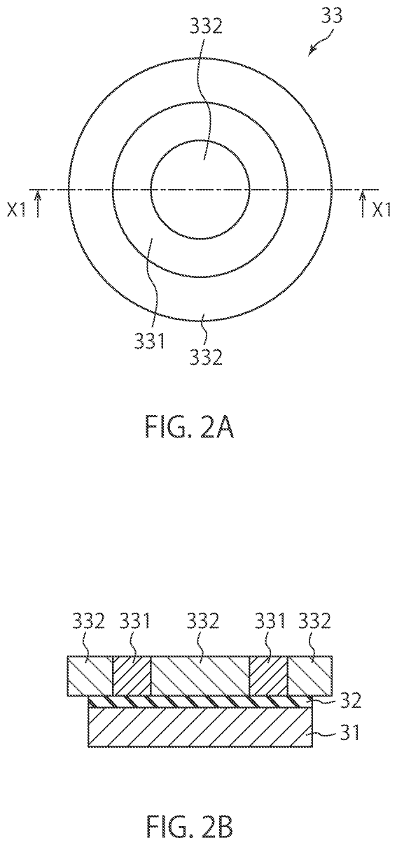

The backing plate 33 holds the target 31 above the chamber 20. The backing plate 33 is connected to a direct-current power supply 203. Herein, the structure of the backing plate 33 will be described with reference to FIGS. 2A and 2B.

FIG. 2A is a plan view of the backing plate 33. FIG. 2B is a cross-section along the line X1-X1 illustrated in FIG. 2A. As illustrated in FIGS. 2A and 2B, the backing plate 33 includes a first portion 331 and a second portion 332 adjacent to the first portion 331.

The shape of the first portion 331 as seen in a plan view is annular, having the center of the backing plate 33 as the center of the first portion 331. The first portion 331 corresponds to the rotational trajectory of the magnet 50. Therefore, the intensity of a magnetic field in the first portion 331 is higher than that in the second portion 332.

Meanwhile, the second portion 332 is provided in an inscribed region inscribed in the first portion 331 and in a circumscribed region circumscribed about the first portion 331. The shape of the second portion 332 provided in the inscribed region as seen in a plan view is circular. The shape of the second portion 332 provided in the circumscribed region as seen in a plan view is annular, concentric with the first portion 331.

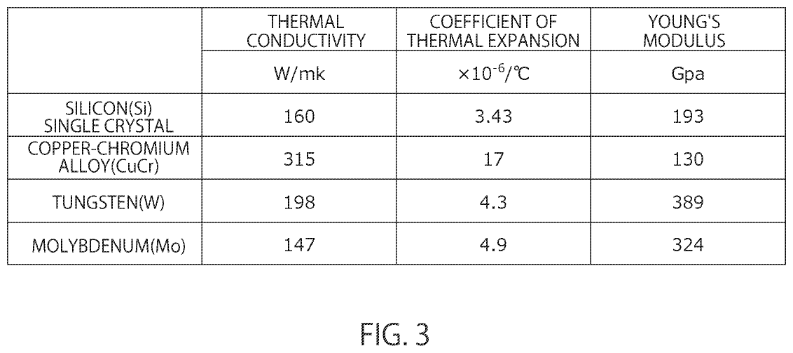

FIG. 3 is a table illustrating the material characteristics of the target 31 and the backing plate 33.

In the chamber 20, a region immediately below the magnet 50 has the highest magnetic field intensity. Therefore, the rare gas 202 is ionized most strongly in the region immediately below the magnet 50. Accordingly, the ionized rare gas 202 collides with a region of the target 31 immediately below the magnet 50, that is, a portion of the target 31 facing the first portion 331 most strongly. Consequently, the first portion 331 has the highest temperature in the backing plate 33 and thus is likely to warp.

To suppress a warp of the backing plate 33 due to heating, the thermal conductivity of a first material included in the first portion 331 is desirably higher than the thermal conductivity of a second material included in the second portion 332. Thus, in the present embodiment, the first material is a copper-chromium alloy (CuCr), and the second material is tungsten (W) or molybdenum (Mo).

According to the table illustrated in FIG. 3, the thermal conductivity of a copper-chromium alloy (CuCr) is sufficiently higher than the thermal conductivity of each of tungsten (W) and molybdenum (Mo). Further, the thermal conductivity of a copper-chromium alloy (CuCr) is sufficiently higher than the thermal conductivity of silicon (Si) single crystal that is the material of the target 31. Therefore, the first portion 331 can sufficiently radiate heat generated by the target 31.

It should be noted that the first material is not limited to a copper-chromium alloy (CuCr), and may be any material that satisfies the aforementioned condition, that is, any material with higher thermal conductivity than that of the second material. For example, an aluminum alloy can be used for the first material.

In addition, to suppress a warp of the backing plate 33, the rigidity of the backing plate 33 is desirably high. Thus, in the present embodiment, the Young's modulus of the second material included in the second portion 332 is higher than the Young's modulus of the first material included in the first portion 331. According to the table illustrated in FIG. 3, the Young's modulus of each of tungsten and molybdenum is significantly higher than the Young's modulus of a copper-chromium alloy.

Further, in the present embodiment, the difference in the coefficient of thermal expansion between the second material (i.e., tungsten or molybdenum) and the material (i.e., silicon single crystal) of the target 31 is smaller than the difference in the coefficient of thermal expansion between the first material (i.e., a copper-chromium alloy) and the material of the target 31. Therefore, damage to the target 31 due to the difference in the coefficient of thermal expansion can be avoided.

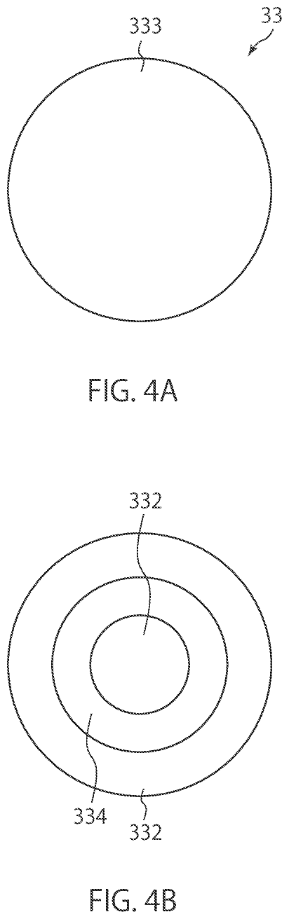

Hereinafter, a part of a step of producing the backing plate 33 will be described with reference to FIGS. 4A and 4B.

First, as illustrated in FIG. 4A, a circular metal plate 333 is formed. The material of the metal plate 333 is the second material (i.e., tungsten or molybdenum).

Next, as illustrated in FIG. 4B, a part of the metal plate 333 is hollowed out in an annular shape. In the metal plate 333, a hollowed-out portion 334 corresponds to the first portion 331, and the remaining portion corresponds to the second portion 332. After that, the hollowed-out portion 334 is filled with the first material (i.e., a copper-chromium alloy). Accordingly, the backing plate 33 illustrated in FIGS. 2A and 2B is completed. It should be noted that the manufacturing method for the backing plate 33 is not limited to the aforementioned method, and other production methods may also be used.

Referring back to FIG. 1, the cooling bath 40 is disposed on the upper face of the backing plate 33. Cooling water 204 flows into and out of the cooling bath 40. The cooling water 204 cools the backing plate 33.

The magnet 50 is provided in the cooling bath 40. The magnet 50 is a permanent magnet configured to rotate about the center of the backing plate 33. A magnetic field of the magnet 50 causes plasma to be generated in the chamber 20.

Described hereinafter is a step of forming a film of a semiconductor device using the aforementioned film deposition apparatus 1.

First, the semiconductor substrate 100 is placed on the stage 10. Next, the chamber 20 is evacuated to a vacuum. Next, alternating-current power is applied to the stage 10 from the AC power supply 201, and direct-current power is applied to the backing plate 33 from the direct-current power supply 203. Concurrently, the magnet 50 is rotated, and the rare gas 202 is introduced into the chamber 20.

The rare gas 202 is ionized by the plasma generated in the chamber 20, and collides with the target 31. Accordingly, silicon atoms are sputtered from the target 31. The sputtered silicon atoms deposit on the surface of the semiconductor substrate 100, and consequently, the film 101 is formed on the semiconductor substrate 100.

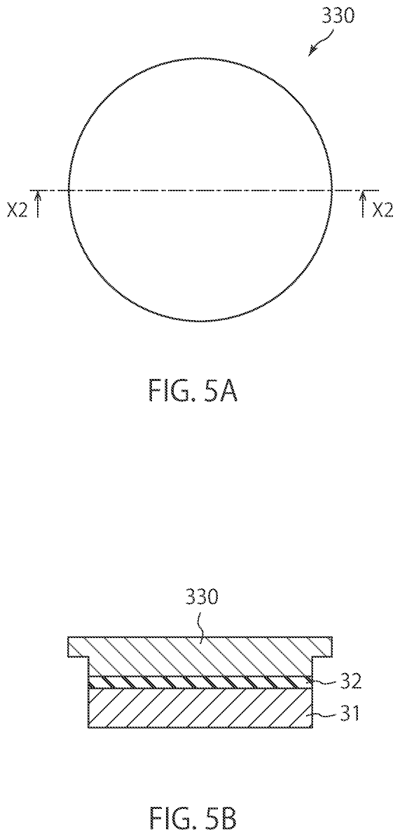

Hereinafter, a backing plate according to Comparative Example will be described with reference to FIGS. 5A and 5B. FIG. 5A is a plan view of the backing plate according to Comparative Example. FIG. 5B is a cross-section along the line X2-X2 illustrated in FIG. 5A.

As illustrated in FIGS. 5A and 5B, a backing plate 330 according to Comparative Example is not segmented into the first portion 331 and the second portion 332. The backing plate 330 includes the first material of the first portion 331, that is, a copper-chromium alloy.

When the film 101 is formed on the semiconductor substrate 100 by attaching the backing plate 330 according to Comparative Example to the film deposition apparatus 1 instead of the backing plate 33, direct-current power is applied to the backing plate 330.

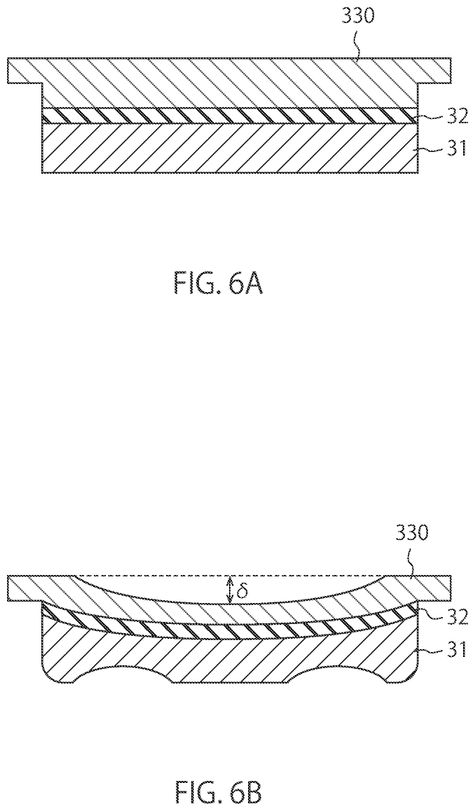

FIG. 6A is a cross-sectional view of the backing plate 330 to which direct-current power is not applied. FIG. 6B is a cross-sectional view of the backing plate 330 to which direct-current power is applied.

When direct-current power is applied to the backing plate 330, the backing plate 330 is heated by sputtering. In such a case, the backing plate 330 warps downward as illustrated in FIG. 6B. The amount δ of warp at this time can be represented by the following expression.

$$δ ∝ \frac{3 {L}^{2} ( 1 - v ) t}{{Ed}^{2}} ( α 1 - α 2 ) Δ T \qquad ( Expression 1 )$$

Parameters in the above expression are as follows.
α1: the coefficient of thermal expansion of the material of the backing plate 33
α2: the coefficient of thermal expansion of the material of the target 31
t: the thickness of the target 31
d: the thickness of the backing plate 33
L: the length of the backing plate 33
ΔT: temperature

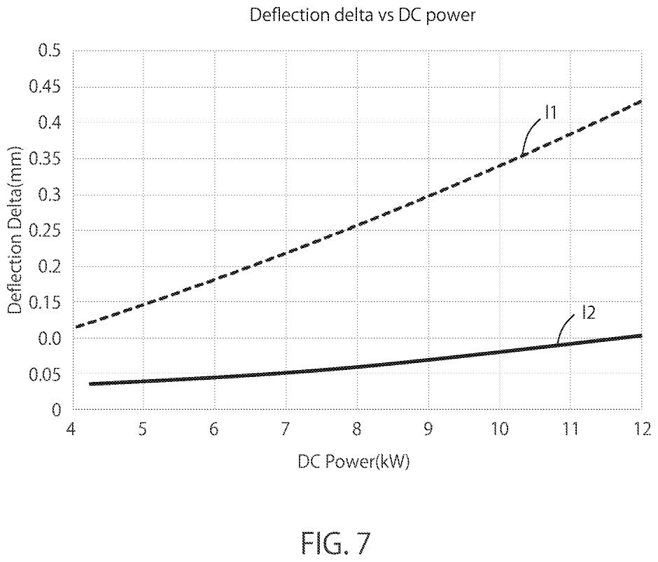

FIG. 7 is a graph illustrating the relationship between direct-current power and the amount of warp of a backing plate. In FIG. 7, the abscissa axis indicates direct-current power applied to a backing plate. Meanwhile, the ordinate axis indicates the amount δ of warp of the backing plate. The dotted line indicates the characteristics of the backing plate 330 according to Comparative Example. The solid line indicates the characteristics of the backing plate 33 according to the present embodiment.

When a film is formed with a plasma sputtering apparatus that includes the backing plate 330 according to Comparative Example, ionization of the rare gas 202 is promoted if the direct-current power applied to the backing plate 330 is high. Therefore, in such a case, the film formation time is shortened, and consequently, productivity of film formation improves.

However, as illustrated in the above expression and FIG. 7, as the direct-current power applied to the backing plate 330 is higher, the amount δ of warp of the backing plate 330 also becomes larger. If the amount δ of warp is large, the bonding material 32 that joins the target 31 to the backing plate 330 is likely to fracture due to fatigue. If the bonding material 32 fractures due to fatigue, it is concerned that fragments of the bonding material 32 may be mixed into the film 101 as foreign matter.

Meanwhile, in the backing plate 33 according to the present embodiment, a material with high thermal conductivity is used for the first portion 331 that faces the rotational trajectory of the magnet 50 and thus is likely to have a high temperature as illustrated in FIGS. 2A and 2B. In addition, a material having a high Young's modulus and also having a small difference in the coefficient of thermal expansion from the target 31 is used for the second portion 332 other than the first portion 331.

Therefore, as illustrated in FIG. 7, a change in the amount δ of warp of the backing plate 33 according to the present embodiment with respect to direct-current power is smaller than that of the backing plate 330 according to Comparative Example.

Therefore, according to the present embodiment, high direct-current power can be applied to the backing plate 33. Accordingly, the time required for forming the film 101 is shortened, and productivity of film formation can thus be improved. Although direct-current power is applied to the backing plate 33 in the present embodiment, alternating-current power may also be applied. In such a case, since high alternating-current power can be applied to the backing plate 33, the time required for forming the film 101 is shortened, and productivity of film formation can thus be improved as in the case where direct-current power is applied.

Further, in the present embodiment, the difference in the coefficient of thermal expansion between the backing plate 33 and the target 31 is also small. This can suppress fatigue fractures of the bonding material 32, and thus can avoid mixing of foreign matter into the film 101. Accordingly, the quality of film formation can also be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A film deposition apparatus comprising:
a target including a film deposition material;
a backing plate to which the target is to be joined; and
a magnet disposed above the backing plate, wherein
the backing plate includes a first portion facing the magnet and a second portion in which an intensity of a magnetic field generated by the magnet is lower than in the first portion,
thermal conductivity of a first material included in the first portion is higher than that of a second material included in the second portion, and
a Young's modulus of the second material is higher than that of the first material.

2. The film deposition apparatus according to claim 1, wherein the second material is a metal or an alloy having the Young's modulus of greater than 300 GPa.

3. The film deposition apparatus according to claim 1, wherein the first material is a metal containing at least one of copper and aluminum.

4. The film deposition apparatus according to claim 2, wherein the second material is a metal containing at least one of molybdenum and tungsten.

5. The film deposition apparatus according to claim 1, wherein a difference in a coefficient of thermal expansion between the second material and the film deposition material is smaller than a difference in a coefficient of thermal expansion between the first material and the film deposition material.

6. The film deposition apparatus according to claim 1, wherein
the magnet is configured to rotate about a center of the backing plate, and
the first portion faces a rotational trajectory of the magnet.

7. The film deposition apparatus according to claim 5, wherein a shape of the first portion as seen in a plan view is annular.

8. The film deposition apparatus according to claim 7, wherein
the second portion includes an inscribed region inscribed in the first portion, and a circumscribed region circumscribed about the first portion,
the inscribed region is circular, and
the circumscribed region is annular.

9. The film deposition apparatus according to claim 1, wherein the film deposition material is silicon.

10. The film deposition apparatus according to claim 1, wherein the target is joined to the backing plate with a bonding material containing indium.

11. A sputtering target comprising:
a target including a film deposition material; and
a backing plate to which the target is to be joined, wherein
the backing plate includes a first portion and a second portion in which an intensity of a magnetic field is lower than in the first portion,
thermal conductivity of a first material included in the first portion is higher than that of a second material included in the second portion, and
a Young's modulus of the second material is higher than that of the first material.

12. A manufacturing method for a semiconductor device, comprising applying direct-current power or alternating-current power to a backing plate having joined thereto a target including a film deposition material, and causing a magnet disposed above the backing plate to generate a magnetic field, thereby forming a film including the film deposition material on a semiconductor substrate disposed below the target, wherein
the backing plate has formed therein a first portion and a second portion in which an intensity of the magnetic field generated by the magnet is lower than in the first portion,
the first portion is formed with a first material having higher thermal conductivity than that of the second portion, and
the second portion is formed with a second material having a higher Young's modulus than that of the first material.
